(19) United States
(12) Patent Application Publication
(10) Pub. No.: US 2025/0379555 A1
(43) Pub. Date: Dec. 11, 2025

(54) HIGH-FREQUENCY ACOUSTIC-WAVE RESONATOR AND FILTER COMPRISING THE SAME

(71) Applicant: SHANGHAI INSTITUTE OF MICROSYSTEMS AND INFORMATION TECHNOLOGY, CHINESE ACADEMY OF SCIENCES, Shanghai (CN)

(72) Inventors: Xin Ou, Shanghai (CN); Jinbo Wu, Shanghai (CN); Shibin Zhang, Shanghai (CN); Pengcheng Zheng, Shanghai (CN); Liping Zhang, Shanghai (CN)

(73) Assignee: SHANGHAI INSTITUTE OF MICROSYSTEMS AND INFORMATION TECHNOLOGY, CHINESE ACADEMY OF SCIENCES, Shanghai (CN)

(21) Appl. No.: 18/878,002

(22) PCT Filed: Jun. 13, 2023
(86) PCT No.: PCT/CN2023/099857

§ 371 Date: Dec. 20, 2024

(30) Foreign Application Priority Data
Jun. 27, 2022 (CN) 202210742047.X

(51) Int. Cl. H03H 9/17; H03H 9/02

(52) U.S. Cl. CPC H03H 9/175; H03H 9/02228

(57) ABSTRACT

The present disclosure discloses a high-frequency acoustic wave resonator and a filter comprising the same. The high-frequency acoustic wave resonator includes, a support substrate, a bottom electrode, a piezoelectric film, and an interdigital transducer stacked in sequence from bottom to top; the interdigital transducer comprises a first bus bar and a plurality of first electrodes spaced apart; one same side of each of the plurality of first electrodes is connected to the first bus bar; the product of the spacing between the centers of adjacent first electrodes in the plurality of first electrodes and the frequency of the target mode is less than the acoustic velocity of the support substrate; the target mode is a high-order mode excited in the high-frequency acoustic wave resonator under the influence of a longitudinal electric field. The acoustic wave resonator provided by the present application is constructed on a heterogeneously integrated substrate.

### TECHNICAL FIELD

The present disclosure relates to the field of microelectronics technology, and more particularly, to a high-frequency acoustic wave resonator and a filter comprising the same.

### BACKGROUND

In modern communication industries, the demands for signal quality are increasingly stringent, and the competition for communication spectrum resources is becoming more intense. Low loss, wide bandwidth, tunable frequency, and stable temperature characteristics, have become common pursuit goals in the communication industry. Acoustic resonators include Surface Acoustic Wave (SAW) resonators and Bulk Acoustic Wave (BAW) resonators. Due to their small size, wide bandwidth, and high Q-factor, acoustic resonators are currently widely used in the communication field. Among them, BAW resonators achieve higher frequencies easily by thinning the piezoelectric film, as the resonant frequency is inversely proportional to the thickness.

However, as the frequency increases, the suspended piezoelectric film becomes thinner, making the structure more fragile and heat dissipation more difficult. Moreover, traditional BAW-SMR (Solidly Mounted Resonator) introduces a multilayer Bragg reflector structure to confine acoustic energy within the piezoelectric film to obtain high-Q resonators. This significantly increases the manufacturing complexity and production costs.

### SUMMARY

To address the technical problems of manufacturing difficulty and complex structure of high-frequency acoustic wave resonators in the prior art, the present application discloses, on one aspect, a high-frequency acoustic wave resonator, comprising, a support substrate, a bottom electrode, a piezoelectric film, and an interdigital transducer, which are stacked in sequence from bottom to top
the interdigital transducer includes a first bus bar and a plurality of first electrodes spaced apart, with one same side of each of the plurality of first electrodes connected to the first bus bar;
the product of a spacing between centers of adjacent first electrodes in the plurality of first electrodes and a frequency of a target mode is less than an acoustic velocity of the support substrate; the target mode is a high-order mode excited in the high-frequency acoustic wave resonator under the influence of a longitudinal electric field.

Optionally, the resonant frequency of the target mode is determined by the thickness of the piezoelectric film, the bulk acoustic wave velocity of the piezoelectric film, the type of load, and the thickness of the load; the load includes the interdigital transducer;

the phase velocity of the target mode along a first direction is determined by the period of the interdigital transducer and the resonant frequency, and the phase velocity along the first direction is greater than or equal to 5,000 meters per second; the period of the interdigital transducer is the spacing between the centers of adjacent first electrodes in the plurality of first electrodes; and the first direction is parallel to the surface of the piezoelectric film.

Optionally, the waveform corresponding to the target mode is selected from one of a high-order Lamb wave, a high-order horizontal shear wave, and a high-order Rayleigh mode.

Optionally, the acoustic velocity of a slow shear wave in a second direction within the support substrate is greater than the phase velocity of the target mode along the first direction; the second direction is parallel to the first direction and perpendicular to the direction of the first electrodes.

Optionally, a first side edge of the first bus bar is spaced apart from a side edge of a neighboring bottom electrode by a predetermined distance; the first side edge is the side edge adjacent to the bottom electrode.

Optionally, further comprising an insulating member;
a first through-hole is formed in the piezoelectric film;
the first through-hole corresponds to the first bus bar, and the insulating member is disposed within the first through-hole; and
the insulating member is made of a non-piezoelectric insulating material.

Optionally, further comprising a bonding layer;
the bonding layer is located between the support substrate and the bottom electrode; and
the bonding layer comprises a non-metallic material or a metallic material.

Optionally, further comprising a low-acoustic velocity medium layer;
the low acoustic-velocity medium layer is located between the support substrate and the bottom electrode; and
the low acoustic-velocity medium layer comprises a non-metallic material or a metallic material.

Optionally, the support substrate comprises a laminated structure of a first substrate and a high acoustic-velocity substrate;
the first substrate is made of a material that is easy to form and process; and
the material of the high-acoustic-velocity substrate is selected from one of silicon carbide, diamond, diamond-like materials, sapphire, aluminum nitride, and silicon nitride, which having different crystal structures and cut orientations.

Optionally, the thickness of the high-acoustic-velocity substrate is greater than or equal to 0.5 times the spacing between the centers of adjacent first electrodes in the plurality of first electrodes.

On the other aspect, the present application discloses a filter, comprising the aforementioned high-frequency acoustic wave resonator.

By adopting the above technical solutions, the high-frequency acoustic wave resonator provided by the present application has the following beneficial effects:
the high-frequency acoustic wave resonator includes, a support substrate, a bottom electrode, a piezoelectric film, and an interdigital transducer stacked from bottom to top; the interdigital transducer includes a first bus bar and a plurality of first electrodes spaced apart, with one same side of each of the plurality of first electrodes connected to the first bus bar; a product of a spacing between centers of adjacent first electrodes in the plurality of first electrodes and a frequency of a target mode is less than an acoustic velocity of the support substrate; the target mode is a high-order mode excited in the high-frequency acoustic wave resonator under the influence of a longitudinal electric field. The acoustic wave resonator provided by the present application does not include Bragg reflector layers, thereby reducing manufacturing difficulty and eliminating parasitic effects caused by Bragg reflector layers. Overall, it features a simple structure and a high-strength piezoelectric film while still ensuring the quality of the acoustic wave resonator.

### BRIEF DESCRIPTION OF THE DRAWINGS

To more clearly illustrate the technical solutions of the embodiments of the present application, the following provides a brief description of the drawings used in the description of the embodiments. It is apparent that the drawings described below are merely some embodiments of the present application, and those skilled in the art can derive other drawings without exercising inventive skill based on these drawings.

FIG. 1 shows a schematic diagram of an exemplary acoustic wave resonator according to an embodiment of the present application;

FIG. 2 shows a partial schematic diagram of an exemplary acoustic wave resonator according to an embodiment of the present application;

FIG. 3 shows a Bulk Acoustic Wave (BAW) resonator with a Bragg reflector layer;

FIG. 4 shows a simulated admittance curve of the structure shown in FIG. 3;

FIG. 5 shows a mode shape diagram corresponding to the structure shown in FIG. 3;

FIG. 6 shows an SH1 mode resonator with a Bragg reflector layer;

FIG. 7 shows a simulated admittance curve of the structure shown in FIG. 6;

FIG. 8 shows a mode shape diagram corresponding to the structure shown in FIG. 6;

FIG. 9 shows a BAW resonator without a Bragg reflector layer;

FIG. 10 shows a simulated admittance curve of the structure shown in FIG. 9;

FIG. 11 shows a mode shape diagram corresponding to the structure shown in FIG. 9;

FIG. 12 shows an SH1 mode resonator without a Bragg reflector layer;

FIG. 13 shows a simulated admittance curve of the structure shown in FIG. 12;

FIG. 14 shows a mode shape diagram corresponding to the structure shown in FIG. 12;

FIG. 15 shows an admittance curve of resonators with different numbers of interdigital electrode pairs based on the structure shown in FIG. 12;

FIG. 16 shows a mode shape diagram of resonators with different numbers of interdigital electrode pairs based on the structure shown in FIG. 12;

FIG. 17 shows an admittance curve of an exemplary resonator according to an embodiment of the present application;

FIG. 18 shows a mode shape diagram of an exemplary resonator according to an embodiment of the present application;

FIG. 19 shows an admittance curve of another exemplary resonator according to an embodiment of the present application;

FIG. 20 shows a mode shape diagram of another exemplary resonator according to an embodiment of the present application.

### REFERENCE NUMERALS

1—Support substrate
2—Bottom electrode
3—Piezoelectric film
4—Interdigital transducer
41—First bus bar
42—First electrode
43—Second bus bar
44—Second electrode
5—Bragg reflector layer
6—Plate-like top electrode
7—Top interdigital electrode
8—Low-acoustic-velocity medium layer.

### DETAILED DESCRIPTION

The technical solutions of the embodiments of the present application will be clearly and completely described with reference to the accompanying drawings. It is evident that the embodiments described herein are merely some embodiments of the present application and not all possible embodiments. Based on the embodiments of the present application, those skilled in the art can derive all other embodiments without exercising inventive skill, and such derived embodiments are within the scope of protection of the present application.

Here, the terms “an embodiment” or “embodiment” refer to specific features, structures, or characteristics that may be included in at least one embodiment of the present application. In the description of the present application, it should be understood that terms such as “upper,” “lower,” “top,” and “bottom” indicate directional or positional relationships based on the orientations or positions shown in the accompanying drawings. These terms are used solely for the convenience of describing and simplifying the present application and do not indicate or imply that the device or component must have a specific orientation, structure, or operation in a particular direction. Therefore, such directional terms should not be construed as limiting the present application. Additionally, terms like “first,” “second,” etc., are used solely for descriptive purposes and should not be understood as indicating or implying relative importance or implicitly specifying the number of the technical features indicated. Consequently, features designated as “first,” “second,” etc., may explicitly or implicitly include one or more of such features. Moreover, terms such as “first,” “second,” etc., are used to distinguish similar objects and are not intended to describe a specific order or sequence. It should be understood that such terms can be interchanged as appropriate so that the embodiments of the present application described herein can be implemented in an order other than those illustrated or described herein.

Although the numerical ranges and parameters described herein are approximate values intended to illustrate the broad scope of the present disclosure, the values listed in specific examples are reported as accurately as possible. However, any numerical value inherently includes some degree of error resulting from the standard deviation found in their respective tests and measurements.

When a numerical range is disclosed herein, the range is considered to be continuous and includes the minimum and maximum values of the range, as well as every value in between. Furthermore, when the range refers to integers, it includes every integer between the minimum and maximum values of the range. Additionally, when multiple ranges are provided to describe a feature or characteristic, the ranges may be combined. In other words, unless otherwise specified, all ranges disclosed herein should be understood to include any and all sub-ranges encompassed by the disclosed ranges. For example, a specified range of “1 to 10” should be understood to include any and all sub-ranges between the minimum value of 1 and the maximum value of 10. Exemplary sub-ranges of the range 1 to 10 include, but are not limited to, 1 to 6.1, 3.5 to 7.8, and 5.5 to 10.

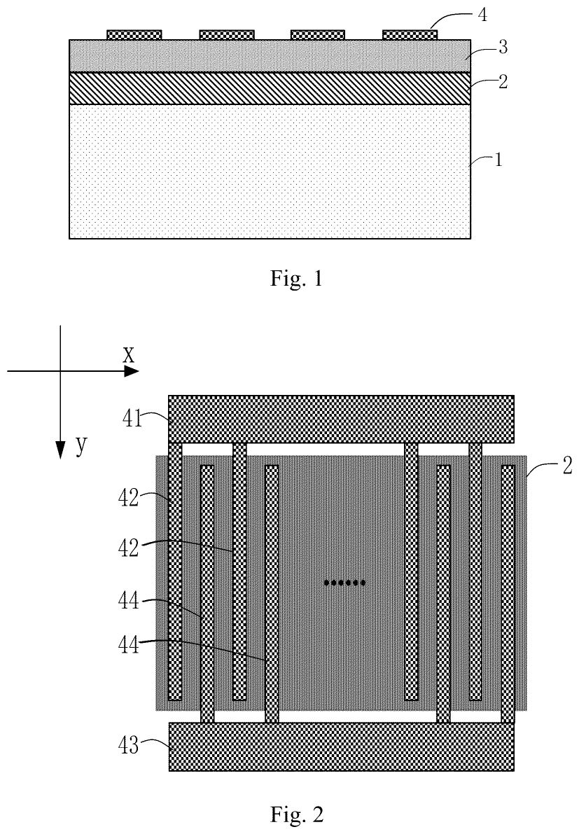

Typically, resonators in the prior art include Bragg reflector layers and a sandwich structure layered thereon, with a plate-like top electrode on the piezoelectric film. In such structures, spurious modes excited by longitudinal electric fields are difficult to eliminate by adjusting the electrode thickness, piezoelectric film thickness, and other parameters. Additionally, Bragg reflector layers have high process complexity and usually utilize metals as high acoustic impedance layers. Even with patterned bottom electrodes, it is impossible to avoid parasitic effects introduced by Bragg reflector layers. Therefore, how to simplify the structure while retaining the advantages of high-order modes excited by longitudinal fields becomes the key to achieving high-frequency, wide-bandwidth applications. Accordingly, referring to FIGS. 1-2, FIG. 1 is a structural schematic diagram of an exemplary acoustic wave resonator according to an embodiment of the present application. FIG. 2 is a partial schematic diagram of an exemplary acoustic wave resonator according to an embodiment of the present application. The present application discloses a high-frequency acoustic wave resonator, which includes, in order from bottom to top, a support substrate 1, a bottom electrode 2, a piezoelectric film 3, and an interdigital transducer 4. The interdigital transducer 4 includes a first bus bar 41 and a plurality of first electrodes 42 spaced apart. One same side of each of the plurality of first electrodes 42 is connected to the first bus bar 41. The product of the spacing between adjacent first electrodes 42 in the plurality of first electrodes 42 and the frequency of the target mode is less than the acoustic velocity of the support substrate 1. The target mode is a high-order mode excited in the high-frequency acoustic wave resonator under the influence of an electric field. The acoustic wave resonator provided by the present application does not include a Bragg reflector layer structure composed of high and low acoustic impedance layers or a cavity structure that makes the piezoelectric film suspended. It has a simple and stable structure, and ensures that the acoustic wave excited by the electric field is confined within the piezoelectric film 3 without leaking into the substrate, thereby ensuring the quality factor of the resonator. Besides metal electrodes, no other conductive materials are used, thereby avoiding parasitic effects introduced by Bragg reflector layers. The target mode is excited by longitudinal electric field, with vibration primarily in the thickness direction. The electrode coverage and the number of electrode pairs have little effect on the target mode, reducing the requirements for photolithography precision and improving the flexibility of capacitance control and filter design.

In one feasible embodiment, the resonant frequency of the target mode is determined by the thickness of the piezoelectric film 3, the bulk acoustic wave velocity of the piezoelectric film 3, the type of load, and the thickness of the load. The load includes the interdigital transducer 4. The phase velocity of the target mode along a first direction (such as the x-axis direction in FIG. 2) is determined by the period of the interdigital transducer 4 and the resonant frequency, and the phase velocity along the first direction is greater than or equal to 5,000 meters per second. The period of the interdigital transducer 4 is the spacing between the centers of adjacent first electrodes 42 in the plurality of first electrodes 42. The first direction is parallel to the surface of the piezoelectric film 3.

Optionally, referring to FIG. 2, the interdigital transducer 4 further includes a second bus bar 43 and a plurality of second electrodes 44 arranged in spaced intervals. The plurality of first electrodes 42 and the plurality of second electrodes 44 are alternately arranged, and the distance between adjacent second electrodes 44 is equal to that between adjacent first electrodes 42.

Optionally, the interdigital transducer 4 and the bottom electrode 2 can be a single-layer metal film, a multi-layer metal film, or a composite film composed of metal and non-metal materials. The metal film materials can be pure metal materials, alloys, or materials doped with non-metal elements.

Optionally, the type of load can refer to the type of material of the load and can also refer to the structural composition of the load. For example, the load includes an interdigital transducer 4 and an insulating layer.

Optionally, the insulating layer can be an unpatterned layer on the surface of the interdigital transducer 4, or a patterned layer, i.e., only located on the bus bars and electrodes of the interdigital transducer 4.

Optionally, the insulating layer material can be an insulating material such as silicon oxide, aluminum nitride, or silicon nitride.

Optionally, when the load is the interdigital transducer 4, as the density of the interdigital transducer 4 material increases, the resonant frequency of the resonator decreases. As the elastic modulus of the interdigital transducer 4 material increases, the resonant frequency of the resonator increases. As the thickness of the interdigital transducer 4 increases, the resonant frequency of the resonator decreases.

Optionally, the load can further include the interdigital transducer 4 and a metal layer disposed thereon. The metal layer is only located on the bus bars and electrodes of the interdigital transducer 4 and does not cause short-circuiting of the interdigital transducer 4.

In one feasible embodiment, the waveform corresponding to the target mode is selected from one of a high-order Lamb wave, a high-order horizontal shear wave, and a high-order Rayleigh mode.

In one feasible embodiment, the acoustic velocity of a slow shear wave in a second direction (such as the x-axis direction in FIG. 2) within the support substrate 1 is greater than the phase velocity of the target mode along the first direction. The second direction is parallel to the first direction and perpendicular to the direction of the first electrodes 42.

In one feasible embodiment, to further enhance the quality factor of the resonator and prevent the excitation of the leaked bulk acoustic wave modes in the overlapping regions between the interdigital transducer 4 and the bottom electrode 2—which would become a loss source leaking into the support substrate 1—there is no overlapping regions between the bus bars of the interdigital transducer 4 provided by the present application and the bottom electrode 2. Optionally, the bottom electrode 2 is provided with a second through-hole corresponding to the first bus bar 41. Additionally, as shown in FIG. 2, the first side edge of the first bus bar 41 is spaced a predetermined distance from the side edge of the adjacent bottom electrode 2; the first side edge refers to the side edge adjacent to the bottom electrode 2. In other words, the bottom electrode 2 can be patterned to create a predetermined gap between its side edge and the adjacent bus bar. In another feasible embodiment, the acoustic wave resonator further includes an insulating member. A third through-hole is formed in the piezoelectric film 3, corresponding to the first bus bar 41, and the insulating member is disposed within the third through-hole. The insulating member is made of a non-piezoelectric insulating material. This means that the piezoelectric film 3 in the projection area of the bus bar of the interdigital transducer 4 is removed and filled with the insulating member. Of course, the third through-hole may not be filled, provided that there is no overlapping region between the bottom electrode 2 and the bus bar.

In one feasible embodiment, to improve the quality of the piezoelectric film 3 of the acoustic wave resonator during the fabrication process and to avoid the presence of voids or fractures during bonding, the acoustic wave resonator further includes a bonding layer. The bonding layer is located between the support substrate 1 and the bottom electrode 2 and comprises non-metallic materials or metallic materials. For example, the bonding layer can be made of titanium or silicon oxide.

In one feasible embodiment, when the bonding layer is titanium, since both the bonding layer and the bottom electrode 2 are made of the same type of material, namely metallic materials, it is necessary to prevent the layered structure formed by the bonding layer and the bottom electrode 2 from overlapping with the bus bars of the interdigital transducer 4, thereby reducing the Q-factor of the device. The bonding layer is provided with a first through-hole corresponding to the second through-hole. Alternatively, as described above, by patterning the piezoelectric film 3, the bonding layer does not need to be provided with a first through-hole. To further simplify the structure while improving the quality of the acoustic wave resonator, optionally, the bonding layer and the bottom electrode 2 can be the same layer, i.e., made of the same material.

In one feasible embodiment, to enhance the energy reflection efficiency of the acoustic wave resonator and increase the electromechanical coupling coefficient, the acoustic wave resonator further includes a low-acoustic-velocity medium layer 8. The low-acoustic-velocity medium layer 8 is located between the support substrate 1 and the bottom electrode 2, and its material comprises metallic or non-metallic materials, such as silicon oxide, gold, platinum, etc.

Optionally, the low-acoustic-velocity medium layer 8 and the bonding layer can be the same layer, for example, when both the low-acoustic-velocity medium layer 8 and the bonding layer are made of silicon oxide. Alternatively, the low-acoustic-velocity medium layer 8 and the bonding layer can be different layers. In this case, the acoustic wave resonator includes a laminated structure of a low-acoustic-velocity medium layer 8 and a bonding layer between the support substrate 1 and the bottom electrode 2. The bonding layer can be made of materials such as titanium, nickel, tungsten, niobium, chromium, silicon oxide, or benzocyclobutene (BCB), among others. The material of the low-acoustic-velocity medium layer can be silicon oxide, gold, platinum, etc.

It should be noted that when both the low-acoustic-velocity medium layer 8 and the bonding layer are present and both are made of metallic materials, to further improve the quality factor of the resonator and prevent the interdigital transducer 4 and the bottom electrode 2 from exciting leaked bulk acoustic wave modes in overlapping regions, becoming a loss source leaking into the support substrate 1. The low-acoustic-velocity medium layer 8 and the bonding layer can be patterned, referring to the aforementioned treatment method when the bonding layer is titanium. Similarly, when the acoustic wave resonator only has a low-acoustic-velocity medium layer 8 but it is made of a metallic material, the low-acoustic-velocity medium layer 8 can also be patterned in the same manner as when the bonding layer is titanium.

In one feasible embodiment, to improve the processability of the acoustic wave resonator during the manufacturing process, the support substrate 1 includes a stacked first substrate and a high-acoustic-velocity substrate. The material of the first substrate is a material that is easy to form and process. The material of the high-acoustic-velocity substrate is selected from one of silicon carbide, diamond, diamond-like materials, sapphire, aluminum nitride, and silicon nitride, each having different crystal structures and cut orientations. Optionally, as needed, the support substrate 1 can also be the aforementioned high-acoustic-velocity substrate.

It should be noted that when the support substrate comprises a two-layer structure, including a stacked first substrate and a high-acoustic-velocity substrate, the material of the high-acoustic-velocity substrate can be deposited onto the first substrate through processes such as epitaxial growth or Physical Vapor Deposition (PVD). Generally, the thickness of the high-acoustic-velocity layer is on the micrometer scale, thereby forming a high-acoustic-velocity support substrate. Since the high-acoustic-velocity substrate is relatively thin when the support substrate comprises a two-layer structure, this effectively confines the acoustic waves within the piezoelectric film and prevents their leaking into the substrate. Optionally, the thickness of the high-acoustic-velocity substrate is greater than or equal to 0.5 times the spacing between adjacent first electrodes 42 in the plurality of first electrodes 42. That is, the thickness of the high-acoustic-velocity substrate is greater than or equal to 0.5 times the period of the interdigital transducer 4.

Optionally, the target mode is excited by a longitudinal electric field; the electrode coverage, the period of the interdigital transducer 4, and the in-plane propagation direction have little impact on the target mode. The spurious modes can be suppressed by utilizing the differences in dispersion effects of different modes and the anisotropy of materials.

It should be noted that the differences in dispersion effects of different modes refer to the changes in resonant frequency caused by adjusting the ratio of the thickness of each layer (e.g., piezoelectric film, interdigital transducer, bottom electrode, etc.) to the period of the interdigital transducer 4.

To facilitate the understanding of the technical solutions of the present application and to illustrate the beneficial effects thereof, specific embodiments will be described below.

The following abbreviations are used in the description below:
SH1: First-order Shear Horizontal mode
S1: First-order Symmetric Lamb wave mode
BAW: Bulk Acoustic Wave
TSM: Thickness Shear Mode

### Embodiment 1

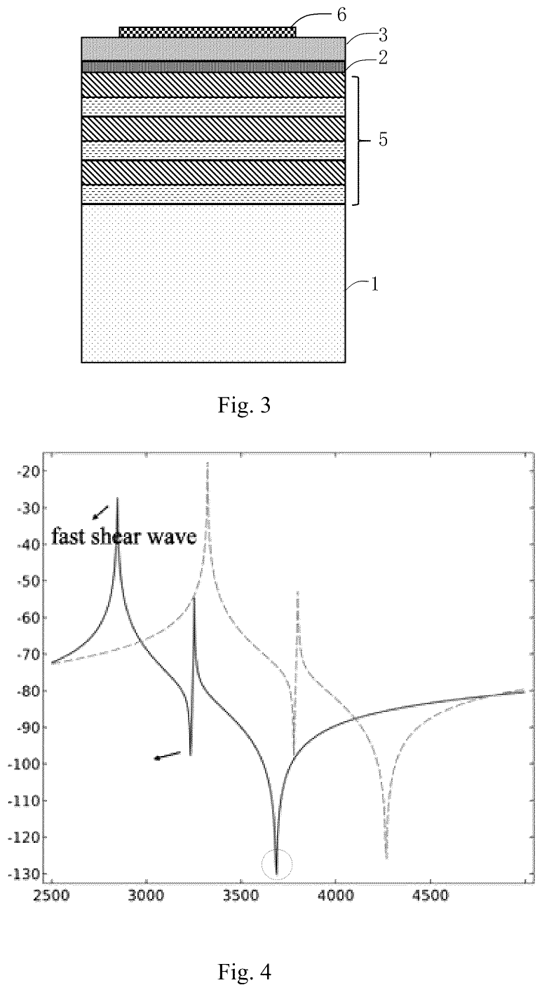

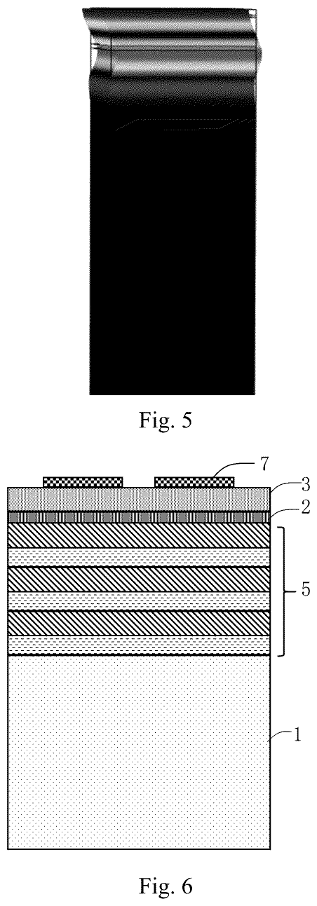

A Bulk Acoustic Wave (BAW) resonator with a Bragg reflector layer 5 is provided, referring to FIGS. 3-5. FIG. 3 is a BAW resonator with a Bragg reflector layer; FIG. 4 is a simulated admittance curve of the structure shown in FIG. 3; and FIG. 5 is a mode shape diagram corresponding to the structure shown in FIG. 3. The piezoelectric film 3 of this BAW resonator is an X-cut lithium niobate film, the support substrate 1 is a silicon substrate, and the Bragg reflector layer 5 comprises a structure of alternating 295 nm silicon oxide and 80 nm platinum repeated three times. In FIG. 4, the thicknesses of the piezoelectric film 3 in Resonator One and Resonator Two are 325 nm and 230 nm, respectively. As shown in FIG. 3, a plate-like top electrode 6 is formed on the piezoelectric film 3. The target mode corresponding to the BAW resonator is the Thickness Shear Mode (TSM). The mode shape diagram shown in FIG. 5 corresponds to the resonance peak indicated by the dashed loop in FIG. 4. From the mode shape diagram in FIG. 5, it can be seen that due to the reflection of the acoustic wave energy caused by the Bragg reflector layer 5, the vibrations are concentrated on the surface of the support substrate 1. In X-cut lithium niobate, there is a phenomenon of coupling between two shear waves, namely the fast shear wave and the slow shear wave. The BAW resonator with sandwich-structures is unable to achieve decoupling of these two modes.

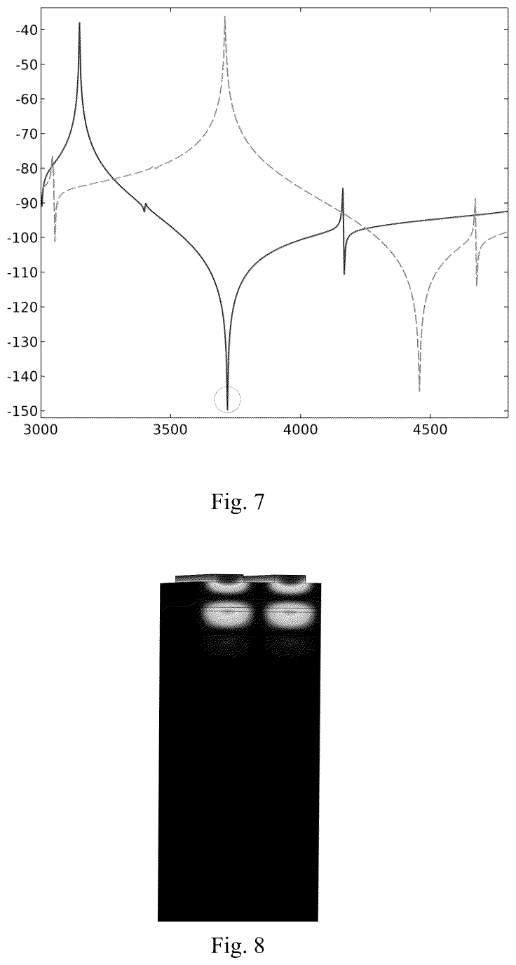

To further illustrate the beneficial effects of the present application, an SH1 mode resonator with a Bragg reflector layer 5 is provided. Referring to FIGS. 6-8, FIG. 6 is an SH1 mode resonator with a Bragg reflector layer; FIG. 7 is a simulated admittance curve of the structure shown in FIG. 6; and FIG. 8 is a mode shape diagram corresponding to the structure shown in FIG. 6. The piezoelectric film 3 of this SH1 mode resonator is an X-cut lithium niobate film, the support substrate 1 is a silicon substrate, and the Bragg reflector layer 5 comprises a structure of alternating 295 nm silicon oxide and 80 nm platinum repeated three times. In FIG. 7, the thicknesses of the piezoelectric film 3 in Resonator One and Resonator Two are 325 nm and 230 nm, respectively. As shown in FIG. 6, a top interdigital electrode 7 is formed on the piezoelectric film 3. The resonator shown in FIG. 6 corresponds to the SH1 mode. The mode shape diagram shown in FIG. 8 corresponds to the resonance peak indicated by the dashed loop in FIG. 6. Comparing the mode shape diagrams in FIGS. 5 and 8, it can be seen that due to the reflection of the acoustic wave energy caused by the Bragg reflector layer 5, whether in the TSM mode or the SH1 mode, the vibrations are concentrated on the surface of the support substrate 1. For this SH1 mode resonator, Resonator One in FIG. 7 has a wavelength of 1.65 micrometers and the corresponding Euler angle of lithium niobite is (24, 90, −90), while Resonator Two has a wavelength of 1.603 micrometers and the corresponding Euler angle of lithium niobite is (27, 90, −90). By selecting appropriate in-plane orientations of the piezoelectric film and thicknesses of the electrode, spurious modes are suppressed. This demonstrates that high-order mode resonators with a bottom electrode 2 and a top interdigital electrode 7 have the advantage of suppressing spurious modes. In other words, based on the spurious mode suppression principle of the present application, designing the piezoelectric film 3 and electrode structure of a resonator with a Bragg reflector layer 5 can achieve spurious mode suppression. It can also be demonstrated that high-order mode resonators with a bottom electrode 2 and a top interdigital electrode 7 have the advantage of suppressing spurious modes.

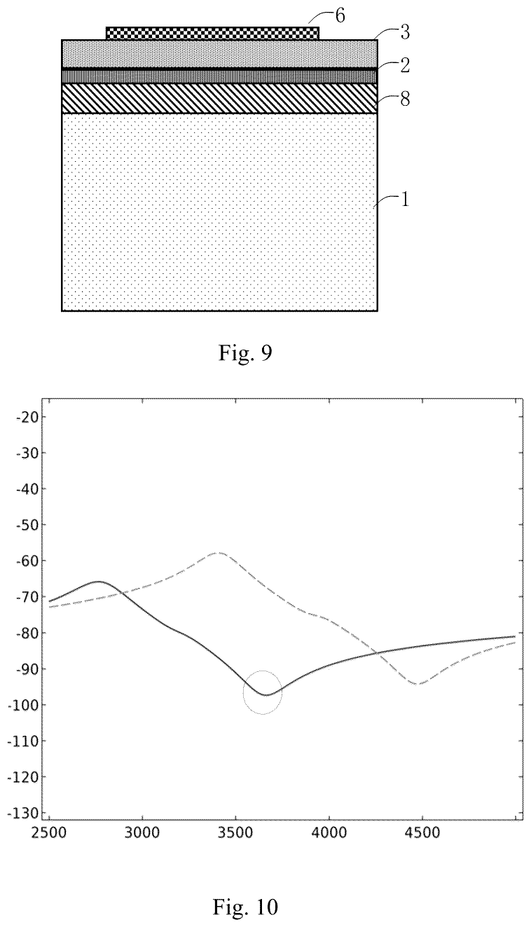

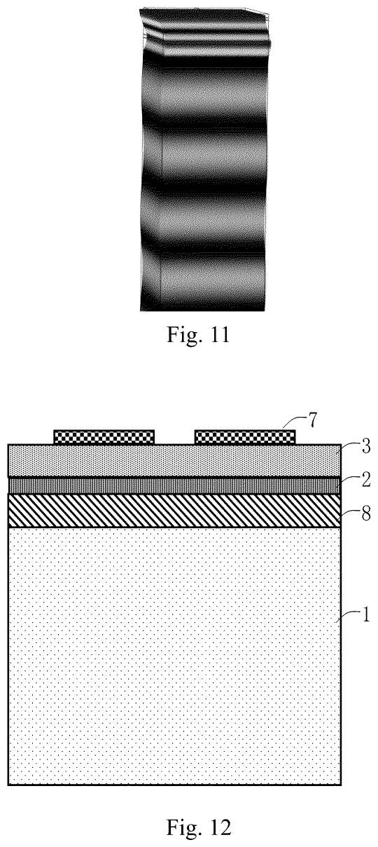

To better illustrate the beneficial effects of the resonator structure without a Bragg reflector layer of the present application, a BAW resonator without a Bragg reflector layer 5 is first provided. Referring to FIGS. 9-11, FIG. 9 is a BAW resonator without a Bragg reflector layer; FIG. 10 is a simulated admittance curve of the structure shown in FIG. 9; and FIG. 11 is a mode shape diagram corresponding to the structure shown in FIG. 9. The piezoelectric film 3 of the BAW resonator in FIG. 9 is an X-cut lithium niobate film, the support substrate 1 is 4H-SiC, and the low-acoustic-velocity medium layer 8 is silicon oxide. In FIG. 10, the thicknesses of the piezoelectric film 3 in Resonator One and Resonator Two are 325 nm and 230 nm, respectively. As shown in FIG. 9, a plate-like top electrode 6 is formed on the piezoelectric film 3. The target mode corresponding to the BAW resonator in FIG. 9 is the TSM mode. The mode shape diagram shown in FIG. 11 corresponds to the resonance peak indicated by the dashed loop in FIG. 10. From the mode shape diagram in FIG. 11, it can be seen that the acoustic energy of the TSM mode leaks significantly into the support substrate, which also leads to a substantial decrease in the quality factor Q, and the admittance ratio of the corresponding admittance curve decreases to 30 dB, which fails to meet requirements of practical applications.

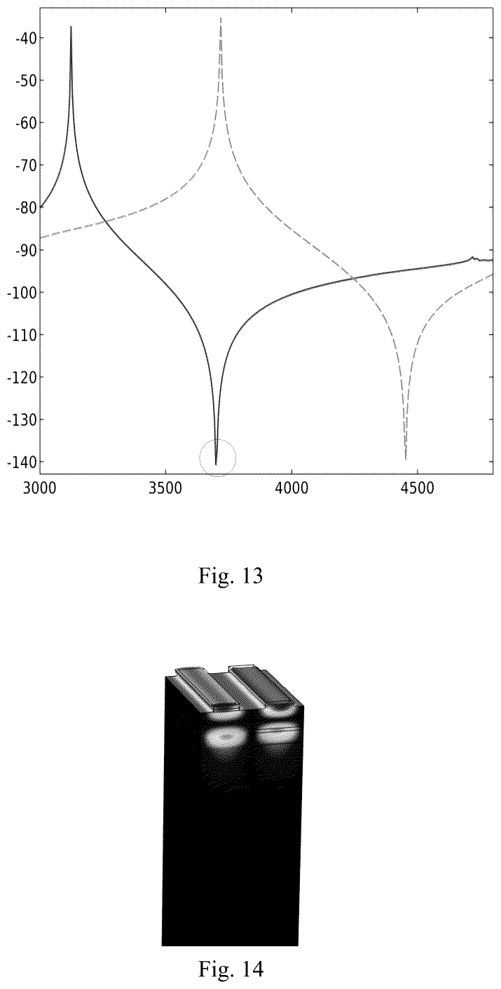

An SH1 mode resonator without a Bragg reflector layer 5 is provided. Referring to FIGS. 12-14, FIG. 12 is an SH1 mode resonator without a Bragg reflector layer; FIG. 13 is a simulated admittance curve of the structure shown in FIG. 12; and FIG. 14 is a mode shape diagram corresponding to the structure shown in FIG. 12. The piezoelectric film 3 of the SH1 mode resonator in FIG. 12 is an X-cut lithium niobate film, the support substrate 1 is 4H-SiC, and the low-acoustic-velocity medium layer 8 is silicon oxide. In FIG. 13, the thicknesses of the piezoelectric film 3 in Resonator One and Resonator Two are 325 nm and 230 nm, respectively. As shown in FIG. 12, a top interdigital electrode 7 is formed on the piezoelectric film 3. The resonator shown in FIG. 12 corresponds to the SH1 mode. For this SH1 mode resonator, Resonator One in FIG. 13 has a wavelength of 1.65 micrometers and the corresponding Euler angle of lithium niobite is (24, 90, −90), while Resonator Two has a wavelength of 1.603 micrometers and the corresponding Euler angle of lithium niobite is (27, 90, −90). The mode shape diagram shown in FIG. 14 corresponds to the resonance peak indicated by the dashed loop in FIG. 13. By comparing the mode shape diagrams in FIGS. 11 and 14, as well as the admittance curves in FIGS. 10 and 13, it can be seen that the SH1 mode resonator corresponding to FIG. 14 not only suppresses spurious modes but also achieves excellent acoustic energy confinement in a structurally simple substrate. From FIG. 13, the effective electromechanical coupling coefficients of Resonator One and Resonator Two in the SH1 mode resonator are 49.6% and 53.6%, respectively, which can meet the bandwidth requirements for all frequency bands below 6 GHz.

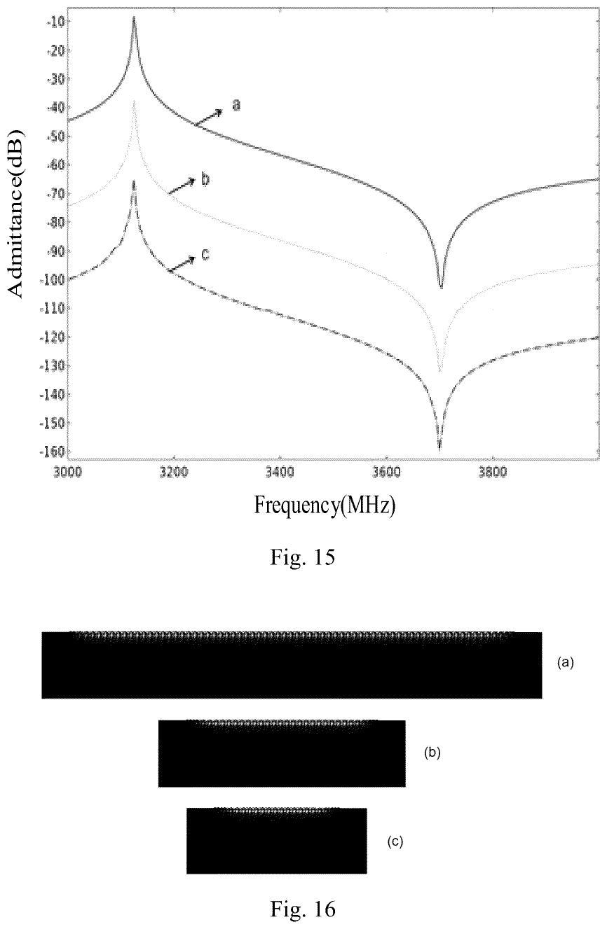

Traditional BAW resonators often require electrodes with large area to suppress high-order spurious modes in the in-plane direction. However, the capacitance of the resonator is proportional to the electrode area, making it difficult to match a 50-ohm termination at high frequencies and greatly limiting the flexibility of filter design. Referring to FIG. 15, FIG. 15 shows admittance curves of resonators with different numbers of interdigital electrode pairs based on the structure shown in FIG. 12. In FIG. 15, curve (a) corresponds to 60 pairs of interdigital electrodes, curve (b) corresponds to 20 pairs of interdigital electrodes, and curve (c) corresponds to 10 pairs of interdigital electrodes. Referring to FIG. 2, each pair of interdigital electrodes includes one first electrode 42 and one second electrode 44. From FIG. 15, it can be seen that the admittance curve shape of the simplified SH1 mode resonator is basically unaffected by the reduction in the number of electrode pairs. When the number of electrode pairs is reduced from 60 to 10, the admittance ratio remains almost unchanged. Referring to FIG. 16, FIG. 16 is a mode shape diagram of resonators with different numbers of interdigital electrode pairs based on the structure shown in FIG. 12. In FIG. 16, Figures (a), (b), and (c) correspond to 60, 20, and 10 pairs of electrodes, respectively. From FIG. 16, the mode shape at the anti-resonant frequencies corresponding to different numbers of electrode pairs still show that the vibrations are well confined to the substrate surface as the number of electrodes decreases. The capacitance of the resonator structure is proportional to the number of interdigital electrode pairs, while the device performance is almost unaffected by the number of electrodes. Therefore, the capacitance can be flexibly adjusted, greatly enhancing the flexibility of filter design.

### Embodiment 2

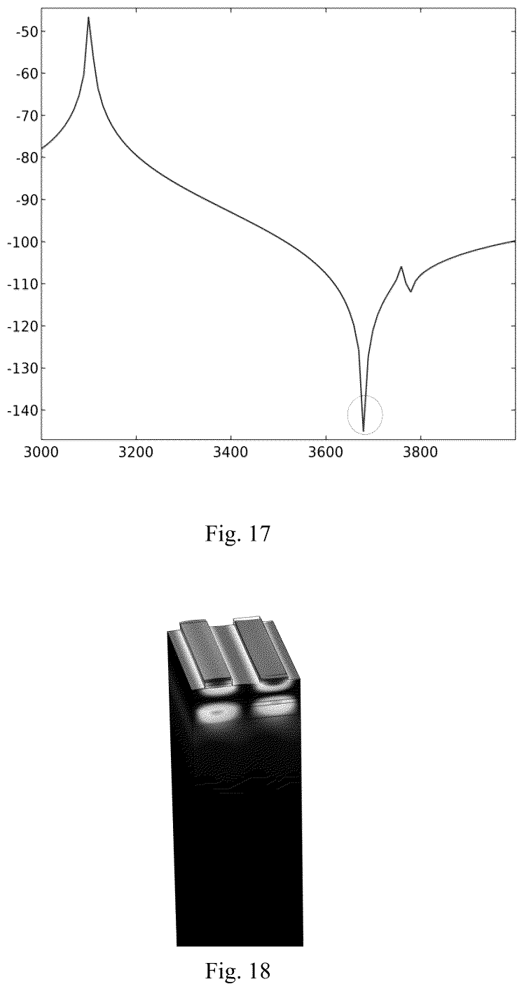

This embodiment provides a resonator, whose structure is shown in FIG. 1. The support substrate 1 is made of sapphire, corresponding to a Euler angle of (44.5, 125, 0). The piezoelectric film 3 is an X-cut lithium niobate film with a wavelength of 1.6 micrometers, and the target mode is the SH1 mode. The admittance curve and mode shape diagram of the resonator are shown in FIGS. 17 and 18, respectively. It should be noted that the mode shape diagram shown in FIG. 18 corresponds to the resonance peak indicated by the dashed loop in FIG. 17. It can be seen that the vibration is primarily concentrated on the substrate surface, and its effective electromechanical coupling coefficient is 50.5%, which also meets the bandwidth requirements for all frequency bands below 6 GHz.

### Embodiment 3

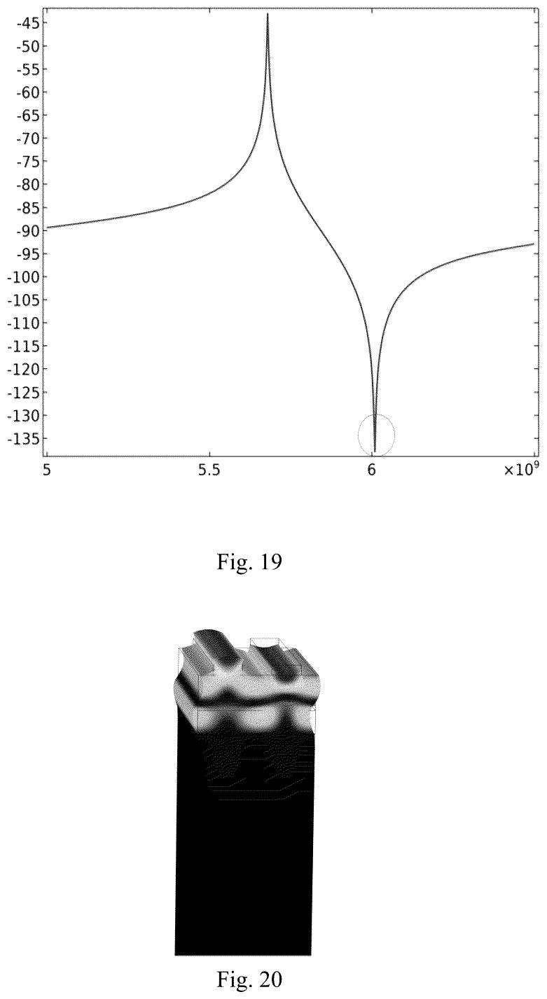

This embodiment provides another resonator, whose structure is shown in FIG. 1. The support substrate 1 is a 6H-SiC substrate, the piezoelectric film 3 is a Y36-cut lithium niobate film with a thickness of 312 nm and a wavelength of 1.2 micrometers. The target mode is a high-order symmetric Lamb wave mode (S1). The admittance curve and mode shape diagram of the resonator are shown in FIGS. 19 and 20, respectively. It should be noted that the mode shape diagram shown in FIG. 20 corresponds to the resonance peak indicated by the dashed loop in FIG. 19. From the mode shape diagram in FIG. 20, it can be seen that the vibration is primarily concentrated on the substrate surface. This mode has a higher acoustic velocity, thus achieving a working frequency of up to 6 GHz with a moderate thickness of the piezoelectric film 3. As shown in FIG. 19, the corresponding effective electromechanical coupling coefficients is 14.8%, which can meet the bandwidth requirements for the 5G WiFi frequency band.

The above-described embodiments are merely exemplary and do not limit the present application. Any modifications, equivalent substitutions, improvements, etc., made within the spirit and principles of the present application are intended to be included within the scope of protection of the present application. cm 1. A high-frequency acoustic wave resonator, comprising, a support substrate, a bottom electrode, a piezoelectric film, and an interdigital transducer stacked in sequence from bottom to top;
wherein the interdigital transducer comprises a first bus bar and a plurality of first electrodes spaced apart, with one same side of each of the plurality of first electrodes connected to the first bus bar;
wherein a product of a spacing between centers of adjacent first electrodes in the plurality of first electrodes and a frequency of a target mode is less than a sound velocity of the support substrate; and
wherein the target mode is a high-order mode excited in the high-frequency acoustic wave resonator under an influence of a longitudinal electric field.

2. The high-frequency acoustic wave resonator of claim 1, wherein a resonant frequency of the target mode is determined by a thickness of the piezoelectric film, a bulk acoustic wave velocity of the piezoelectric film, a type of load, and a thickness of the load;
wherein the load comprises the interdigital transducer;
wherein a phase velocity of the target mode along a first direction is determined by a period of the interdigital transducer and the resonant frequency, and the phase velocity along the first direction is greater than or equal to 5,000 meters per second;
wherein the period of the interdigital transducer is the spacing between the centers of adjacent first electrodes in the plurality of first electrodes; and
wherein the first direction is parallel to a surface of the piezoelectric film.

3. The high-frequency acoustic wave resonator of claim 1, wherein a waveform corresponding to the target mode is selected from one of a high-order Lamb wave, a high-order horizontal shear wave, and a high-order Rayleigh mode.

4. The high-frequency acoustic wave resonator of claim 1, wherein a sound velocity of a slow shear wave in a second direction within the support substrate is greater than the phase velocity of the target mode along the first direction; wherein the second direction is parallel to the first direction and perpendicular to the direction of the first electrodes.

5. The high-frequency acoustic wave resonator of claim 1, wherein a first side edge of the first bus bar is spaced apart from a side edge of a neighboring bottom electrode by a predetermined distance; wherein the first side edge is a side edge adjacent to the bottom electrode.

6. The high-frequency acoustic wave resonator of claim 1, further comprising an insulating member;
wherein a first through-hole is formed in the piezoelectric film;
wherein the first through-hole corresponds to the first bus bar, and the insulating member is disposed within the first through-hole; and
wherein the insulating member is made of a non-piezoelectric insulating material.

7. The high-frequency acoustic wave resonator of claim 5, further comprising a bonding layer;
wherein the bonding layer is located between the support substrate and the bottom electrode; and
wherein the bonding layer comprises both a non-metallic material and a metallic material.

8. The high-frequency acoustic wave resonator of claim 1, further comprising a low-sound-velocity medium layer;
wherein the low-sound-velocity medium layer is located between the support substrate and the bottom electrode; and
wherein the low-sound-velocity medium layer comprises both a non-metallic material and a metallic material.

9. The high-frequency acoustic wave resonator of claim 1, wherein the support substrate comprises a laminated structure of a first substrate and a high-sound-velocity substrate; wherein the first substrate is made of a material that is easy to form and process; and wherein the material of the high-sound-velocity substrate is selected from one of silicon carbide, diamond, diamond-like materials, sapphire, aluminum nitride, and silicon nitride, which have different crystal structures and cut orientations.

10. The high-frequency acoustic wave resonator of claim 9, wherein a thickness of the high-sound-velocity substrate is greater than or equal to 0.5 times the spacing between the centers of adjacent first electrodes in the plurality of first electrodes.

11. A filter, comprising the high-frequency acoustic wave resonator of claim 1.
